(19) United States
(12) Patent Application Publication
(10) Pub. No.: US 2007/0169703 A1
(43) Pub. Date: Jul. 26, 2007

(54) Advanced ceramic heater for substrate processing

(76) Inventors: Brent Elliot, Cupertino, CA (US); Frank Balma, Monte Sereno, CA (US); Alexander Veytser, Mountain View, CA (US); Andrew Josef Widawski Ogilvy, Port Talbot (GB); James Burnett Forrest, Swansea (GB)

Correspondence Address: CARR & FERRELL LLP, 2200 GENG ROAD, PALO ALTO, CA, 94303, US

(21) Appl. No.: 11/509,899

(22) Filed: Aug. 24, 2006

Related U.S. Application Data
(60) Provisional application No. 60/761,737, filed on Jan. 23, 2006.

(51) Int. Cl. H01L 21/306; C23C 16/00

(52) U.S. Cl. 118/728; 156/345.51; 156/914

(57) ABSTRACT

Susceptors are provided that employ layers of CTE-matching materials to reduce the stresses that otherwise lead to cracking and failure. Exemplary CTE-matching materials include metal alloys of aluminum and silicon that can be tailored to specific CTE values by adjusting the ratio of the elements. An exemplary susceptor comprises a CTE-matching material that accommodates the differences in the CTEs of a ceramic material and a thermal barrier layer disposed on opposite sides of the CTE-matching material. Methods are also provided for forming susceptors. These methods comprise assembling the components and bonding the assembly together, such as by diffusion bonding, to produce a susceptor that is a monolithic body.

### CROSS-REFERENCE TO RELATED APPLICATIONS

This application claims priority from U.S. Provisional Patent Application Ser. No. 60/761,737, filed Jan. 23, 2006, and entitled “King Electrostatic Chuck,” which is incorporated herein by reference in its entirety.

### BACKGROUND OF THE INVENTION

1. Field of the Invention

The present invention relates generally to the field of semiconductor fabrication, and more particularly to susceptors for use in processing chambers.

2. Description of Related Art

Semiconductor processing and similar manufacturing processes typically employ thin film deposition techniques such as Chemical Vapor Deposition (CVD), Physical Vapor Deposition (PVD), Vapor Phase Epitaxy (VPE), Reactive Ion Etching, and other typical processing methods. In CVD processing, as well as in other manufacturing techniques, a substrate such as a silicon wafer is secured within a processing chamber by a susceptor and exposed to the particular processing conditions of the process. The susceptor is essentially a pedestal that, in addition to securing the substrate, can in some instances also be used to heat the substrate.

As susceptors are exposed to high operating temperatures and corrosive process gases, and because good thermal conductivity is required for good temperature control, prior art susceptors have been made from a very limited selection of materials, such as aluminum nitride (AlN) ceramic or PBN, silicon dioxide (quartz), graphite, and various metals such as aluminum alloys, nickel alloys, stainless steel alloys, Inconel, etc. Corrosive process gases which are typically used for semiconductor processing generally react with susceptors made with metal alloys. These reactions produce reaction by-products and other effects which can be detrimental to the desired process results. Ceramic materials can be much more resistant to reactions with typical process gases. However, ceramic materials can be mechanically fragile, have limited methods of fabrication due to inherent material properties, and have high manufacturing costs. Optimally, a composite structure of ceramic and metal alloys can be used. However, differences in the coefficients of thermal expansion between these materials can create stresses that can cause cracking of the ceramic and failure of the susceptor. Therefore, what is needed is a composite susceptor that provides good thermal conductivity and good resistance to reactions with typical process gases, while being less susceptible to cracking.

### SUMMARY OF THE INVENTION

An exemplary embodiment of the present invention comprises a susceptor including a substrate support member bonded to a shaft including a chamber mount. The substrate support member includes a ceramic material characterized by a first coefficient of thermal expansion (CTE). The shaft is characterized by a second coefficient of thermal expansion which can be the coefficient of thermal expansion of the material of the chamber mount, or can be the coefficient of thermal expansion of another material within the shaft, such as a thermal barrier layer. The susceptor also includes a CTE-matching layer bonded to the ceramic material and disposed between the ceramic material and the chamber mount. The CTE-matching layer is characterized by a third coefficient of thermal expansion that is between the first and second coefficients of thermal expansion, where “between” is inclusive of the first and second coefficients of thermal expansion. Exemplary materials for the CTE-matching layer include metal alloys and metal matrix composites such as aluminum-silicon alloys and aluminum-silicon carbide composites. In some embodiments, the CTE-matching layer comprises sublayers characterized by the same or different coefficients of thermal expansion.

An exemplary susceptor comprises an electrostatic chuck. The electrostatic chuck includes a dielectric plate having an embedded electrode, first and second manifold plates, and a barrier plate disposed between the first and second manifold plates. A surface of the dielectric plate can be concave or convex, in some embodiments. The dielectric plate includes a dielectric material characterized by a first coefficient of thermal expansion, and the barrier plate includes a material characterized by a second coefficient of thermal expansion. The first manifold plate comprises a CTE-matching material that is characterized by a third coefficient of thermal expansion that is between the first and second coefficients of thermal expansion, where “between” is inclusive of the first and second coefficients of thermal expansion. The first manifold plate is bonded to and between the dielectric plate and the barrier plate, and the second manifold plate is bonded to the barrier plate opposite the first manifold plate. In some embodiments the dielectric plate includes a surface coating comprising a high density dielectric material.

An exemplary method of the present invention comprises forming an assembly and bonding together the components of the assembly. Forming the assembly includes bringing together a substrate support member, a shaft, and a CTE-matching layer. The CTE-matching layer can be part of the substrate support member, part of the shaft, or part of both. The substrate support member includes a ceramic material characterized by a first coefficient of thermal expansion. The shaft includes a metal chamber mount and the shaft is characterized by a second coefficient of thermal expansion that can be the coefficient of thermal expansion of the metal of the chamber mount or of another material of the shaft. The CTE-matching layer is characterized by a third coefficient of thermal expansion that is between the first and second coefficients of thermal expansion, where “between” is inclusive of the first and second coefficients of thermal expansion. When the substrate support member and the CTE-matching layer are brought together, the CTE-matching layer contacts the ceramic material of the substrate support member.

Bonding the assembly comprises bonding together the shaft, the substrate support member, and the CTE-matching layer. Bonding the assembly results in a susceptor that is a monolithic body characterized by an absence of internal interfaces and bonding layers. According to various embodiments, bonding can include diffusion bonding such as solid or liquid phase diffusion bonding. Bonding can also include a welding technique such as cold pressure welding, hot pressure welding, friction welding, explosive welding, or magnetically impelled arc butt welding.

### BRIEF DESCRIPTION OF THE DRAWINGS

FIG. 1 illustrates a cross-section of a susceptor according to an exemplary embodiment of the invention.

FIG. 2 illustrates a cross-section of a susceptor according to another exemplary embodiment of the invention.

FIG. 3 illustrates an exploded a cross-section of the embodiment of FIG. 2 to illustrate a method of forming a susceptor according to an exemplary embodiment of the invention.

FIG. 4 illustrates a cross-section of an electrostatic chuck according to an exemplary embodiment of the invention.

### DETAILED DESCRIPTION

The present invention provides susceptors that employ layers of CTE-matching materials to reduce the stresses that otherwise lead to cracking and failure with repeated thermal cycling. Exemplary CTE-matching materials include metal alloys of aluminum and silicon that are convenient to machine to desired shapes and can be tailored to specific CTE values by adjusting the ratio of the two elements. For high temperature applications, a susceptor can comprise a CTE-matching material that accommodates the differences in the CTEs of a ceramic material of a substrate support, on one side, and a thermal barrier layer disposed on the other side. The thermal barrier layer thermally shields a metal chamber mount from the heat generated at the substrate support. When these materials are bonded together, such as by diffusion bonding, the resulting susceptor is a monolithic body without sharp interfaces and without bonding or interfacial layers.

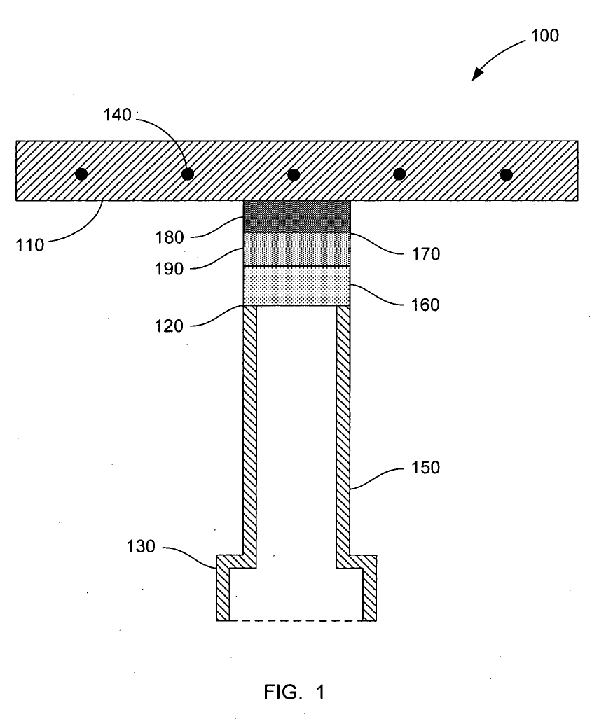

FIG. 1 illustrates a cross-section of an exemplary susceptor 100 according to an embodiment of the invention. The susceptor 100 comprises a substrate support member 110 joined to a shaft 120 including a chamber mount 130. The substrate support member 110 can include one or more conductive elements, for example, RF grids, electrostatic electrodes, or in the case of the illustrated embodiment, a resistive heating coil 140. Although not shown in FIG. 1 for simplicity, the substrate support member 110 can also include various manifolds and apertures for purposes such as supplying a vacuum or a cooling fluid. Also for simplicity, the various conductors and conduits that run within the shaft 120 have also been omitted.

The substrate support member 110, in some embodiments, comprises a ceramic material such as aluminum nitride (AlN). A coefficient of thermal expansion (CTE) of AlN typically can vary between 4.5 and 5.5 parts per million (ppm) in units of inches per inch per degree Celsius. A preferred CTE for AlN is about 5.4 ppm. The CTE of AlN can be varied by adjusting certain factors such as the microstructure and the concentrations of additives such as calcium oxide (CaO), yttrium oxide (Y₂O₃), and magnesium oxide (MgO). Other suitable materials for the substrate support member 110 include boron nitride (BN), magnesium oxide (MgO), and quartz (SiO₂) and other such materials that are suitably thermally conductive and suitably resistant to the corrosive effects of process gases.

The shaft 120 includes a hollow lower portion 150 that includes the chamber mount 130. The lower portion 150 can be made from a metal such as aluminum (Al). To protect the lower portion 150 from heat generated in the substrate support member 110, the shaft 120 can also include a thermal barrier layer 160 between the lower portion 150 and the substrate support member 110. Accordingly, the thermal barrier layer 160 is formed from a thermally insulating material with a low coefficient of thermal conductivity such as aluminum oxide (Al₂O₃). Typically, aluminum oxide has a CTE in the range of about 7.4 to 7.5 ppm. An o-ring (not shown) can be used as a seal between the lower portion 150 and the thermal barrier layer 160. It will be understood that the thermal barrier layer 160 is not essential for susceptors that are not intended for high temperature applications.

Due to the differences in the CTEs of the materials of the substrate support member 110 and the thermal barrier layer 160, the susceptor 100 also includes a CTE-matching layer 170 bonded between the thermal barrier layer 160 and the substrate support member 110. The CTE-matching layer 170 is characterized by a CTE that is intermediate between the CTEs of the materials on either side. In the example shown in FIG. 1, the CTE-matching layer 170 is part of the shaft 120 and is bonded between the thermal barrier layer 160 and the substrate support member 110. In other embodiments, the CTE-matching layer 170 can be part of the substrate support member 110 or a transitional component between the substrate support member 110 and the shaft 120. In those embodiments that do not include a thermal barrier layer 160, the CTE-matching layer 170 has a CTE that is intermediate between the CTEs of the materials of the lower portion 150 and the substrate support member 110. It will be understood that as used herein, when a CTE is described as being “between” two other CTEs, the range of CTEs that are “between” the two other CTEs includes the two other CTEs. Thus, for example, if the CTE-matching layer has a CTE between the CTE of the thermal barrier layer 160 and the substrate support member 110, the CTE of the CTE-matching layer can be equal to the CTE of either of the thermal barrier layer 160 or the substrate support member 110.

The CTE-matching layer 170 is also preferably characterized by high thermal and electrical conductivity and good machinability. Suitable materials for the CTE-matching layer 170 include metal alloys and metal matrix composites. Of the metal alloys, suitable examples include aluminum-silicon alloys, copper-tungsten alloys, and copper-molybdenum alloys. Suitable metal matrix composites include materials having either carbide or graphite particles as the reinforcing component such as aluminum-silicon-carbide, aluminum-graphite, magnesium-graphite, and copper-graphite. For some of these systems, such as the aluminum-silicon system, the CTE of the material can be tailored based on the ratio of silicon to aluminum.

In some embodiments, the CTE-matching layer 170 includes several sub-layers where each sub-layer has a different CTE. For example, in the embodiment shown in FIG. 1, the CTE-matching layer 170 can include two sub-layers. A first sub-layer 180 adjoining the substrate support member 110 can have a CTE close to the CTE of AlN, while a second sub-layer 190 can have a CTE close to that of Al₂O₃. For instance, the first sub-layer 180 can be an alloy of aluminum-silicon, containing 80 weight percent silicon, and having a CTE of about 5.5. The second sub-layer 190 can be another alloy of aluminum-silicon containing 70 weight percent silicon and having a CTE of about 7.4. Alternatively, the CTE-matching layer 170 can be configured to have a composition gradient so that the CTE of the CTE-matching layer 170 also follows a gradient.

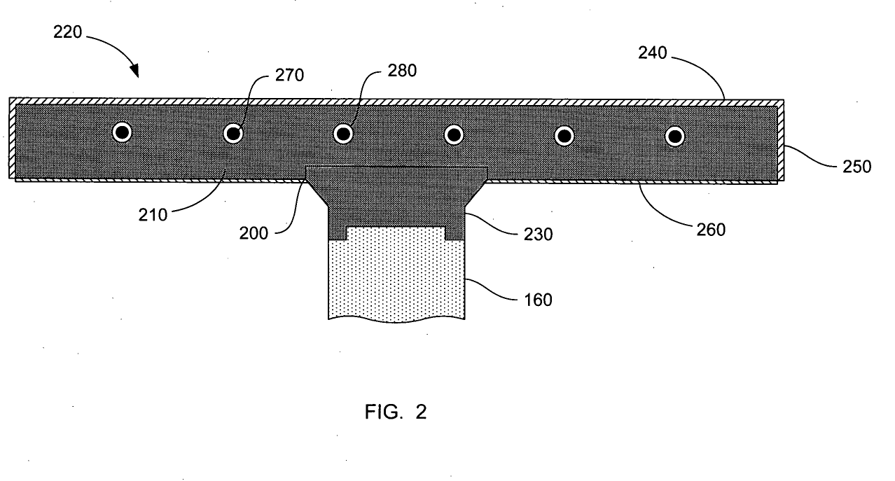

As noted above, the CTE-matching layer 170 can be part of the substrate support member 110 or can be a transitional component between the substrate support member 110 and the shaft 120, in addition to being simply part of the shaft 120 as in FIG. 1. FIG. 2 shows another exemplary embodiment in which a CTE-matching layer 200 is divided into two parts, a part 210 that is a part of a substrate support member 220, and a transitional component 230 between the substrate support member 220 and the thermal barrier layer 160 of the shaft 120 (FIG. 1).

In this embodiment the substrate support member 220 also includes a cover plate 240 and an optional jacket 250, of a suitable material such as AlN, Al₂O₃, or high purity aluminum, bonded to the part 210 of the CTE-matching layer 200. It will be appreciated that, as above, the parts 210 and 230 of the CTE-matching layer 200 can be made of the same or of different materials. The substrate support member 220 can also include on a bottom surface a protective coating 260 of a suitable material such as aluminum oxide, nickel, or high-purity aluminum, that will be compatible with the intended process environment.

In those embodiments in which the susceptor includes a heating coil 270, the substrate support member 220 also includes an electrically insulating sheath 280 around the heating coil 270. In these embodiments the heating coil 270 can be a typical resistive heating element such as nichrome (Ni—Cr). By comparison, the heating coil 140 (FIG. 1) can be made of molybdenum (Mo).

As noted above, the CTE-matching layer 170, 200 is bonded between plates or layers of other materials such as AlN and Al₂O₃. In some embodiments, the bond between the CTE-matching layer 170, 200 and an adjoining material is a diffusion bond. In a diffusion bond, atoms from the materials on both sides of the interface diffuse across the interface so that the resulting transition is characterized by a compositional gradient and a general lack of metallurgical or other discontinuities (e.g., voids, inclusions, intermetallic layers, interfacial layers, etc.) to mark the former interface. A further discussion of bonding methods is presented below.

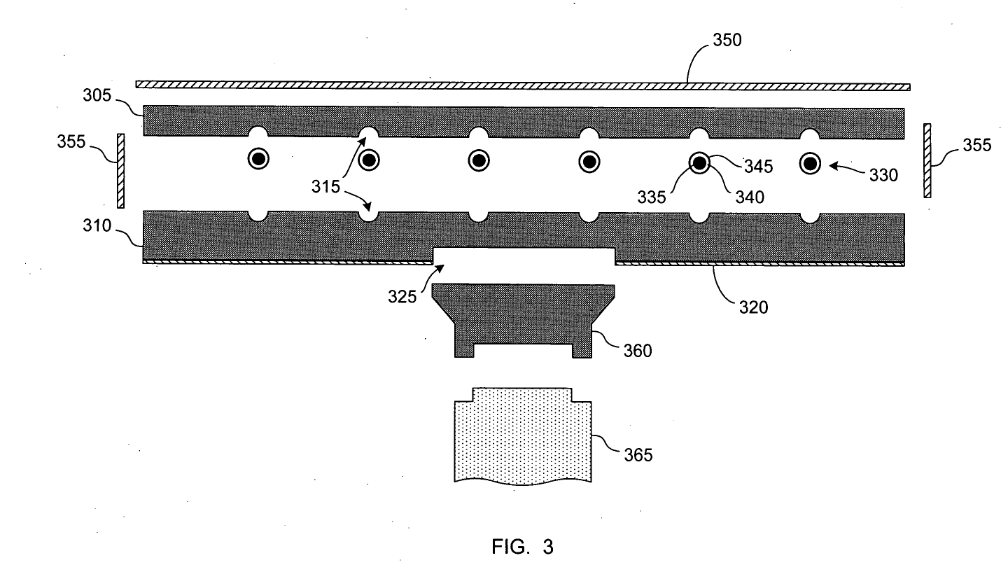

FIG. 3 illustrates an exemplary method for producing a susceptor. FIG. 3 provides an exploded cross-sectional view of the several pieces that are bonded together to form the susceptor shown in FIG. 2. It will be appreciated that the illustration is greatly simplified for clarity, and various features such as apertures, manifolds, and inserts that are necessary to the operation of the susceptor have been omitted. The integration of the omitted features with this method will be apparent to those of ordinary skill in the art.

In the embodiment of FIG. 3, first and second plates 305, 310 of a CTE-matching material are provided as disks, each including a matching groove 315 on one surface thereof. In this particular instance, the second plate 310 also includes a protective coating 320 and a recess 325 on the opposite surface. The coating 320 can be aluminum oxide, nickel, or high-purity aluminum, for example, and is provided to protect the coated surface of the finished susceptor from the process environment.

The plates 305, 310 can have the same composition or different compositions in order to produce sections of the finished susceptor with different CTEs. In some embodiments, multiple such plates are stacked together, each with a different composition, in order to produce a large-scale composition gradient across the finished susceptor. The grooves 315, as well as other features not shown, such as manifolds and apertures, can be defined by machining, for example.

The grooves 315, when properly aligned, form a cavity in a substrate support member of the finished susceptor that receives a heating element 330. The heating element 330 can be, for example, a heating coil 335 surrounded by a sheath 340 in a tubular housing 345. Exemplary materials include nichrome for the heating coil 335, MgO for the sheath 340, and Inconel for the tubular housing 345. It will be appreciated that the method illustrated by FIG. 3 includes aligning the heating element 330 between the two plates 305, 310 and within the grooves 315.

After the plates 305, 310 are brought together with the heating element 325 disposed in the grooves 315 to form a substrate support assembly, a cover 350 and an optional jacket 355 are added to the assembly as shown in FIG. 3. Although not immediately apparent from the cross-section of FIG. 3, it will be understood that the jacket 355 is a cylinder that goes around the assembly, and the cover 350 is a thin disk that is placed on top of the assembly. The cover 350 and jacket 355 can comprise the same or different materials and in some embodiments both comprise AlN.

The method illustrated by FIG. 3 also includes fitting together components of the shaft with the substrate support assembly, as shown. These shaft components can include a transition piece 360 and a thermal barrier layer 365. The transition piece 360 can also comprise a CTE-matching material with either the same or a different composition as the second plate 310. A suitable composition for the thermal barrier layer 365 is aluminum oxide. Although not shown in FIG. 3, another component of the shaft that is joined to the thermal barrier layer 365 is a bottom portion of the shaft comprising, for example, aluminum. As noted above, the thermal barrier layer 365 it not essential in all embodiments and can be omitted so that the transition piece 360 is joined directly to the bottom portion of the shaft. It will also be appreciated that the interlocking configuration of the mating surfaces of the transition piece 360 and the thermal barrier layer 365 (and similarly between transitional component 230 and thermal barrier layer 160 in FIG. 2) is provided merely for illustration and other alignment guides can also be employed, for example, locating pins can be used.

Once the components of the shaft have been assembled together with the substrate support assembly, the entire assembly is subjected to a bonding process. Suitable bonding processes include solid phase diffusion bonding, liquid phase diffusion bonding, cold pressure welding, hot pressure welding, friction welding, explosive welding, magnetically impelled arc butt welding (MIABW), and superplastic forming (DB/SPF). As provided above, these bonding techniques are desirable as they result in a monolithic susceptor where the interfaces between the assembled components are characterized by compositional gradients (except as between pieces with the same composition) and a general lack of discontinuities. Such intimate bonding helps prevent cracks from growing and provides excellent thermal conductivity between components, and in particular between metal and ceramic components.

As used herein, for two dissimilar materials to be “bonded,” requires that an interface between the two materials must be characterized by a compositional gradient between those materials and a general lack of metallurgical or other discontinuities. It will be understood that the meaning of bonded, as used herein, therefore expressly excludes interfaces between two dissimilar materials that are characterized by metallurgical or other discontinuities, and by sharp compositional transitions. Thus, for example, an interface characterized by an interfacial layer of a third material between the two dissimilar materials would not be characterized by a compositional gradient between the dissimilar materials. Accordingly, materials brazed together by an interfacial layer of silver or indium, for instance, would not be bonded within the present definition of the term.

Similarly, as used herein, the terms “bonding” and “bonding together” are limited to producing interfaces between dissimilar materials where the interfaces are characterized as described in the preceding paragraph. It will be understood, therefore, that bonding expressly excludes techniques such as brazing. Furthermore, where a process can produce the requisite interface under some conditions, but not produce that interface under other conditions (e.g., due to insufficient time, temperature, pressure, etc.) it will be understood that “bonding” and “bonding together” expressly excludes those instances where the conditions are insufficient to produce the requisite interfaces.

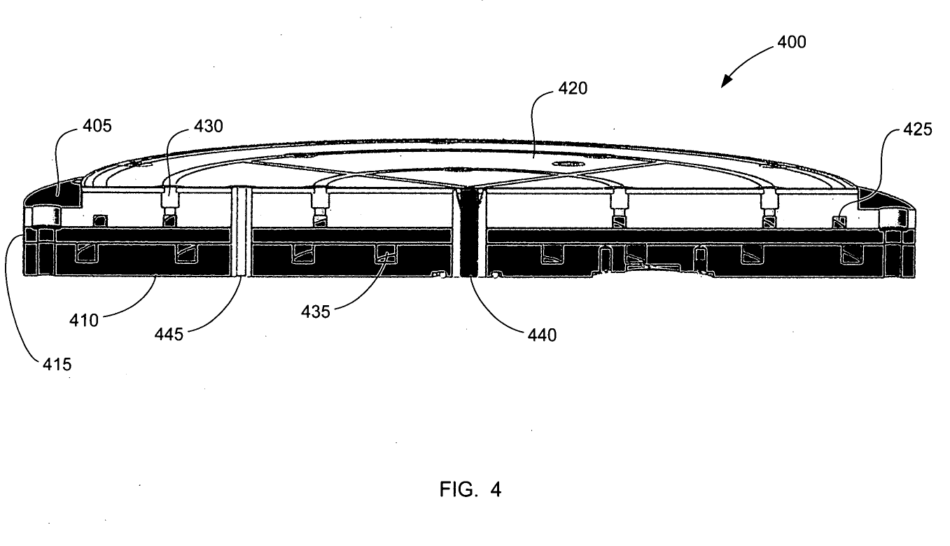

FIG. 4 shows a cross-sectional view of an exemplary susceptor embodiment in which the susceptor comprises an electrostatic chuck 400. The electrostatic chuck 400 can be used, for example, to apply radio-frequency (RF) power to a substrate as well as to conduct heat to and from the substrate. The electrostatic chuck 400 comprises a first manifold plate 405, a second manifold plate 410, a barrier plate 415 disposed between the two manifold plates 405, 410, and a dielectric plate 420 with an embedded electrode (not shown) disposed above the first manifold plate 405.

When these components are bonded together, as by the methods discussed herein, the resulting electrostatic chuck 400 is a monolithic piece with no bonding or interfacial layers to impede heat transfer or chemically react with typical process gases, as are used in the prior art. Accordingly, it will be appreciated that the various interfaces shown between the plates 405-420 in FIG. 4, though initially present before bonding, are not part of the finished electrostatic chuck 400. The same is true for the embodiments shown in FIGS. 1 and 2.

The embedded electrode in the dielectric plate 420 is configured to generate an electrostatic attractive force in order to secure a substrate (not shown) to the dielectric plate 420. The dielectric material of the dielectric plate 420 electrically isolates the embedded electrode from the substrate being processed. Suitable compositions for the dielectric plate 420 include aluminum oxide, aluminum nitride, boron nitride, and silicon carbide and can be formed by techniques such as plasma spray coating, sintering, hot pressing, or other methods. In some embodiments the surface of the dielectric plate 420 is coated with a high density dielectric coating formed, for instance, by Physical Vapor Deposition (PVD) or Chemical Vapor Deposition (CVD). Materials suitable for the dielectric plate 420 are also suitable for the surface coating and can be used together in any combination. The surface coating can be formed, in some embodiments, after the remainder of the electrostatic chuck 400 has been bonded.

The first manifold plate 405 includes a first manifold 425 that in some embodiments is used to distribute gases such as argon or helium or others as a heat transfer medium to cool a backside of the substrate. The first manifold 425 can include, for example, porous dielectric inserts 430 extending from openings in the first manifold 425, through apertures in the dielectric plate 420, and to the backside of the substrate. In operation, a cooling gas such as helium is introduced into the first manifold 425 and is provided through the porous dielectric inserts 430 to the backside of the substrate. The second manifold plate 410 includes a second manifold 435 that in some embodiments allows water to circulate within the second manifold plate 410 to cool the electrostatic chuck 400. In the disclosed embodiment of FIG. 4, each of the manifolds 425, 435 is formed between a groove in the respective manifold plate 405, 410 and a surface of the barrier plate 415.

The electrostatic chuck 400 also comprises a thermocouple hole 440 and a lift pin hole 445. The thermocouple hole 440 is disposed through the plates 405-420 to allow a thermocouple to contact the backside of the substrate. The lift pin hole 445 is provided with a lift pin that is used to raise the substrate off of the dielectric plate 420 when processing is complete. Both the thermocouple hole 440 and the lift pin hole 445 can include a cylindrical insert, as shown in FIG. 4. The insert serves to electrically insulate the manifold plates 405-415 and can be made from dielectric materials such as aluminum oxide. Such features as the aforementioned thermocouple hole and lift pin holes can also be utilized in embodiments such as those illustrated by FIGS. 1-3, but are omitted therefrom for clarity. Other features have been omitted from FIG. 4 for clarity, such as a conductor to bring power to the embedded electrode.

The first manifold plate 405 comprises a CTE-matching material. The second manifold and barrier plates 410, 415 can also be CTE-matching materials, or both can be metals such as aluminum, or the barrier plate 415 can be a CTE-matching material while the second manifold plate 410 is a metal. As discussed above, CTE values for the CTE-matching materials can be selected to accommodate the adjoining materials. Further, a mismatch between the CTE-matching material of the first manifold plate 405 and the dielectric material of the dielectric plate 420 can be chosen to impart either a concave or convex surface to the dielectric plate 420. Where the CTE of the dielectric plate 420 exceeds that of the first manifold plate 405, for example, the surface of the dielectric plate 420 will become convex as the electrostatic chuck 400 is heated.

In the foregoing specification, the invention is described with reference to specific embodiments thereof, but those skilled in the art will recognized that the invention is not limited thereto. Various features and aspects of the above-described invention may be used individually or jointly. Further, the invention can be utilized in any number of environments and applications beyond those described herein without departing from the broader spirit and scope of the specification. The specification and drawings are accordingly, to be regarded as illustrative rather than restrictive. It will be recognized that the terms “comprising,” “including,” and “having,” as used herein, are specifically intended to be read as open-ended terms of art.

What is claimed is:

1. A susceptor comprising:
a substrate support member including a ceramic material having a first coefficient of thermal expansion;
a shaft including a chamber mount and a thermal barrier layer having a second coefficient of thermal expansion; and
a CTE-matching layer disposed between the ceramic material and the chamber mount, bonded to the ceramic material, and having a third coefficient of thermal expansion between the first and second coefficients of thermal expansion, the thermal barrier layer being disposed between the chamber mount and the CTE-matching layer.

2. The susceptor of claim 1 wherein
the thermal barrier layer is bonded to the CTE-matching layer.

3. The susceptor of claim 1 wherein the thermal barrier layer comprises aluminum oxide.

4. The susceptor of claim 1 wherein the ceramic material of the substrate support member comprises aluminum nitride.

5. The susceptor of claim 1 wherein the ceramic material of the substrate support member is selected from the group consisting of boron nitride, magnesium oxide, and quartz.

6. The susceptor of claim 1 wherein the chamber mount comprises aluminum.

7. The susceptor of claim 1 wherein the CTE-matching layer comprises an aluminum-silicon alloy.

8. The susceptor of claim 1 wherein the CTE-matching layer comprises a metal alloy.

9. The susceptor of claim 8 wherein the metal alloy is selected from the group consisting of copper-tungsten alloys and copper-molybdenum alloys.

10. The susceptor of claim 1 wherein the CTE-matching layer comprises a metal matrix composite.

11. The susceptor of claim 10 wherein the metal matrix composite comprises aluminum-silicon carbide.

12. The susceptor of claim 10 wherein the metal matrix composite is selected from the group consisting of aluminum-graphite, magnesium-graphite, or copper-graphite.

13. The susceptor of claim 1 wherein the CTE-matching layer is composed of a first sublayer having a first sublayer coefficient of thermal expansion and a second sublayer having a second sublayer coefficient of thermal expansion and wherein
the first sublayer coefficient of thermal expansion is between the first coefficient of thermal expansion of the substrate support member and the second sublayer coefficient of thermal expansion, and
the second sublayer coefficient of thermal expansion is between the second coefficient of thermal expansion of the shaft and the first sublayer coefficient of thermal expansion.

14. The susceptor of claim 1 wherein the ceramic material comprises a surface layer of the substrate support, and CTE-matching material comprises a body of the substrate support.

15. The susceptor of claim 1 wherein the CTE-matching material comprises a portion of the shaft.

16. The susceptor of claim 1 wherein the substrate support member further includes
a dielectric plate comprising the ceramic material and having an electrode disposed therein, and
the CTE-matching layer.

17-28. (canceled)
